(19) United States
(12) Patent Application Publication
(10) Pub. No.: US 2007/0188166 A1
(43) Pub. Date: Aug. 16, 2007

(54) Magnetic head testing apparatus and method of testing a magnetic head

(75) Inventor: Song Woo Suk, Kawasaki (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: FUJITSU LIMITED, Kawasaki (JP)

(21) Appl. No.: 11/418,130

(22) Filed: May 5, 2006

(30) Foreign Application Priority Data
Feb. 15, 2006 (JP) 2006-37731

(51) Int. Cl. G01R 33/12

(52) U.S. Cl. 324/210

(57) ABSTRACT

A magnetic head testing apparatus and a method of testing a magnetic head cause electromagnetic waves to act upon a magnetic head and therefore can test the characteristics of a magnetic head more precisely and improve the quality of magnetic heads. The magnetic head testing apparatus includes: a magnetic field generating unit for causing a magnetic field to act upon a tested object on which a magnetic head including an MR element is formed; a resistance detecting unit for measuring changes in resistance of the MR element of the magnetic head formed on the tested object when the intensity of the magnetic field is increased and decreased by the magnetic field generating unit; and an electromagnetic wave generating unit for causing electromagnetic waves to act upon the tested object to detect the characteristics of the tested object in an environment where electromagnetic waves act thereupon.

### BACKGROUND OF THE INVENTION

1. Field of the Invention

The present invention relates to a magnetic head testing apparatus and a method of testing that test the characteristics of a magnetic head used in a magnetic disk apparatus.

2. Related Art

A magnetic head used in a magnetic disk apparatus includes a reproduction element and a recording element inside a single head and is formed by forming a magnetic film or the like in a predetermined pattern on a wafer made of ceramic. During actual manufacturing, a large number of magnetic heads are fabricated on a single wafer and are ultimately formed as diced sliders that each includes a reproduction element and a recording element.

An MR element (MagnetoResistive element) is used as the reproduction element of the magnetic head. The MR element uses a magnetoresistive effect whereby the direction of magnetization changes and in turn the magnetic resistance changes when a magnetic field is applied from the outside.

During the manufacturing stage, a magnetic head equipped with an MR element is subjected to a characteristics test that measures the change in resistance when an external magnetic field is applied and judges whether the characteristics of the element are defective or non-defective (see, for example, Patent Document 1). Such characteristics tests are carried out in a state where the wafer on which the magnetic heads have been fabricated has been cut into row bars where magnetic heads are aligned in a row. That is, an alternating current is supplied to a coil to generate an alternating magnetic field to be applied to a row bar, the row bar is disposed inside the alternating magnetic field, the voltage that appears across both ends of each MR element in a state where a predetermined sense current is supplied to the individual MR elements is measured, and changes in the resistance of the MR element are detected to test the characteristics of the MR element.

Patent Document 1

Japanese Laid-Open Patent Publication No. H09-16921

In this way a characteristics test for the reproduction element in particular of a magnetic head fundamentally measures the changes in resistance in the external magnetic field described above. However, a magnetic head is externally influenced not only by a magnetic field but also by heat and electromagnetic waves, and to test resistance to such factors, magnetic characteristics are also tested in an environment where the row bars are heated. Also, since the structures of the elements formed on a magnetic head have become extremely minute in recent years to enable the high-density recording of media, there is now the risk of a fall in the characteristics and durability of the MR element due to the influence of external electromagnetic waves.

### SUMMARY OF THE INVENTION

The present invention was conceived to solve the problem described above and it is an object of the present invention to provide a magnetic head testing apparatus and a method of testing a magnetic head that can test the characteristics of a magnetic head with higher precision by causing external electromagnetic waves to act upon the magnetic head and therefore can improve the quality of magnetic heads.

To achieve the stated object, a magnetic head testing apparatus according to the present invention includes: a magnetic field generating unit for causing a magnetic field to act upon a tested object on which a magnetic head including an MR element is formed; a resistance detecting unit for measuring changes in resistance of the MR element of the magnetic head formed on the tested object when the intensity of the magnetic field is increased and decreased by the magnetic field generating unit; and an electromagnetic wave generating unit for causing electromagnetic waves to act upon the tested object and detecting the characteristics of the tested object in an environment where electromagnetic waves act thereupon.

The electromagnetic wave generating unit may include a transmitter that can vary the intensity of the electromagnetic waves that act upon the tested object.

The electromagnetic wave generating unit may include an antenna such that an orientation, distance, and disposed position thereof relative to the tested object are variable.

A method of testing a magnetic head causes a magnetic field to act upon a tested object on which a magnetic head including an MR element is formed and detects a resistance of the MR element with respect to the applied magnetic field to test whether the MR element is defective or non-defective, wherein when the magnetic field acts upon the tested object, electromagnetic waves are caused to simultaneously act on the tested object to detect the characteristics of the MR element and to judge whether the MR element is defective or non-defective.

According to the magnetic head testing apparatus and method of testing according to the present invention, when a magnetic field is applied to a tested object to test the characteristics of an MR head formed on a magnetic head, it is possible to carry out tests with electromagnetic waves simultaneously acting on the tested object, and therefore magnetic heads can be tested with higher reliability.

### BRIEF DESCRIPTION OF THE DRAWINGS

The aforementioned and other objects and advantages of the present invention will become apparent to those skilled in the art upon reading and understanding the following detailed description with reference to the accompanying drawings.

In the drawings:

FIG. 1 is a diagram useful in explaining the overall construction of a magnetic head testing apparatus according to the present invention; and

FIGS. 2A to 2D are diagrams showing examples of antennas used in an electromagnetic wave generating means of the testing apparatus.

### DESCRIPTION OF THE PREFERRED EMBODIMENTS

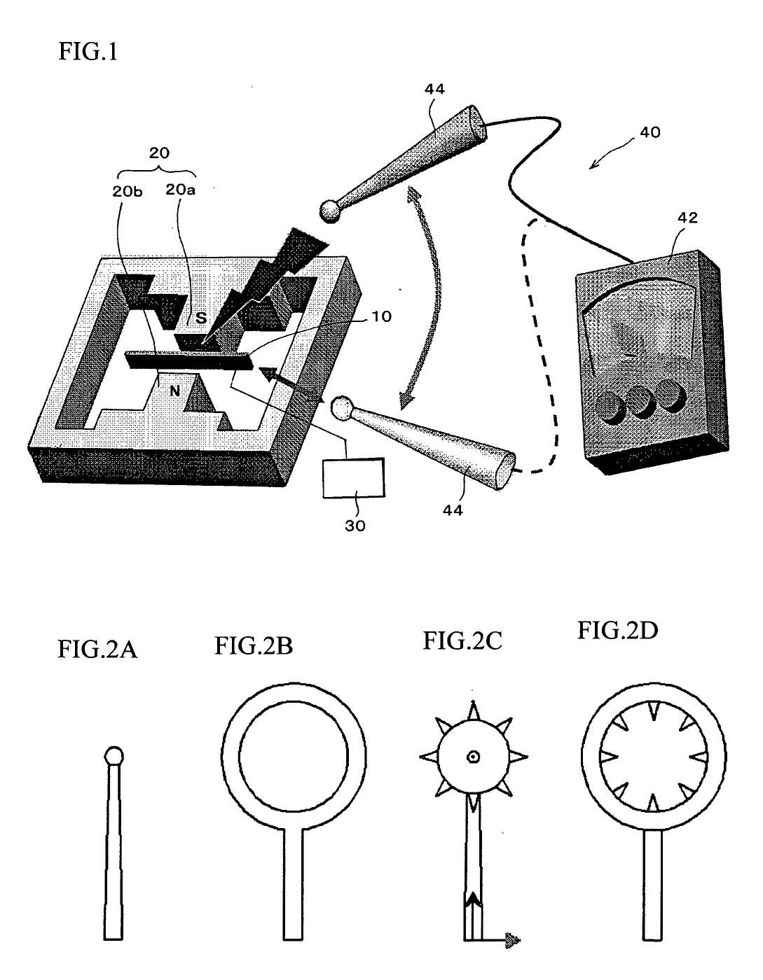

FIG. 1 schematically shows the construction of a magnetic head testing apparatus according to the present invention.

A tested object 10 that is to be tested by the testing apparatus according to the present invention is a row bar cut out from a wafer on which magnetic heads have been fabricated. The testing apparatus according to the present invention includes a magnetic field generating means 20 for generating a magnetic field that acts upon the tested object 10, a resistance detecting means 30 for measuring changes in the resistance of the MR elements of the individual magnetic heads formed on the tested object 10 relative to the strength of the magnetic field when the strength of the magnetic field is increased and decreased by the magnetic field generating means 20, and an electromagnetic wave generating means 40 for causing electromagnetic waves to act upon the tested object 10 from outside.

The magnetic field generating means 20 causes an alternating magnetic field to act upon the tested object 10 and includes a power supply unit that supplies an alternating current to a coil and a control unit for carrying out control that increases and decreases the alternating current. In FIG. 1, the magnetic field generating means 20 that causes a magnetic field to act upon the tested object 10 is schematically shown as a construction where an N pole 20a and an S pole 20b are disposed facing each other. The row bar that is the tested object 10 is disposed between the N pole 20a and the S pole 20b.

The resistance detecting means 30 measures the resistance of the MR elements and includes a sense current power supply that supplies a sense current to an MR element formed on the tested object 10 and a voltage measuring unit that detects the voltage that appears across both ends of the MR element. The change in resistance that occurs when a magnetic field acts on the MR element from outside is found from the voltage of the voltage measuring unit and the sense current.

The electromagnetic wave generating means 40 that causes electromagnetic waves to act on the tested object 10 from outside includes a transmitter 42 for electromagnetic waves and an antenna 44 that transmits the electromagnetic waves toward the tested object 10. The transmitter 42 can adjust the transmission frequency and intensity of the electromagnetic waves. The antenna 44 shown in FIG. 1 is formed as a rod and the distance from the tested object 10, the disposed position, and disposed orientation of the antenna 44 can be appropriately adjusted so that the electromagnetic waves act upon the tested object 10 disposed inside the magnetic field generated by the magnetic field generating means 20. Note that the number of antennas 44 that cause electromagnetic waves to act upon the tested object 10 is not limited to one and a plurality of antennas 44 may be disposed.

When using the testing apparatus according to the present invention, as shown in FIG. 1, the row bar (tested object 10) is disposed inside the magnetic field of the magnetic field generating means 20 and while the magnetic field produced by the magnetic field generating means 20 acts upon the tested object 10, the electromagnetic wave generating means 40 causes electromagnetic waves to act on the tested object 10 and thereby tests the tested object 10.

Changes in the resistance of the MR element of the tested object 10 due to the intensity of the magnetic field that acts upon the tested object 10 can be measured by setting the magnetic field that acts upon the tested object 10 from the magnetic field generating means 20 in a predetermined intensity range, increasing and decreasing the magnetic field within such range, and measuring the resistance while doing so. The change in resistance of the MR element with respect to the magnetic field is measured in the same way as conventional characteristics tests for MR elements.

In the present embodiment, in addition to measuring the changes in resistance with respect to the magnetic field, by causing electromagnetic waves to act upon the tested object 10, it is possible to detect how the resistance of the tested object 10 changes with respect to the magnetic field in an environment where electromagnetic waves act upon the tested object 10. When testing the effects of the electromagnetic waves, by controlling the transmitter 42 of the electromagnetic wave generating means 40 to change the intensity and frequency of the electromagnetic waves that act upon the tested object 10, it is possible to detect the characteristics of the MR element of the tested object 10 with respect to the effects of various types of electromagnetic waves.

In this way, according to the testing apparatus according to the present embodiment, since it is possible to investigate the characteristics of an MR element in an environment where electromagnetic waves act upon the tested object 10 simultaneously with a magnetic field acting upon the tested object 10, it is possible to test the effect of electromagnetic waves on the magnetic head in addition to the magnetoresistance characteristics of the magnetic head, and therefore magnetic heads of higher quality can be supplied.

It should be obvious that in actual tests, the tested object 10 may be evaluated by carrying out tests of the magnetoresistance characteristics with no electromagnetic waves acting upon the tested object 10 and tests of the magnetoresistance characteristics with electromagnetic waves acting upon and affecting the tested object 10.

FIGS. 2A to 2D show several forms of the antenna 44 used by the electromagnetic wave generating means 40. FIG. 2A shows an example of a rod-shaped antenna, FIG. 2B shows an example of an antenna where the end of a rod is ring-shaped, FIG. 2C shows an example where a plurality of needle-like protrusions are disposed at the end of a rod, and FIG. 2D shows an example where the end of a rod is ring-shaped and needle-like protrusions are provided on the inner circumferential surface of the ring.

In this way, it is possible to use an antenna with a suitable form as the antenna that causes the electromagnetic waves to act upon the tested object 10.

What is claimed is:

1. A magnetic head testing apparatus comprising:
magnetic field generating means for causing a magnetic field to act upon a tested object on which a magnetic head including an MR element is formed;
resistance detecting means for measuring changes in resistance of the MR element of the magnetic head formed on the tested object when the intensity of the magnetic field is increased and decreased by the magnetic field generating means; and
electromagnetic wave generating means for causing electromagnetic waves to act upon the tested object and detecting the characteristics of the tested object in an environment where electromagnetic waves act thereupon.

2. A magnetic head testing apparatus according to claim 1, wherein the electromagnetic wave generating means includes a transmitter that can vary the intensity of the electromagnetic waves that act upon the tested object.

3. A magnetic head testing apparatus according to claim 1, wherein the electromagnetic wave generating means includes an antenna such that an orientation, distance, and disposed position thereof relative to the tested object are variable.

4. A method of testing a magnetic head where a magnetic field is caused to act upon a tested object on which a magnetic head including an MR element is formed and a resistance of the MR element with respect to the applied magnetic field is detected to test whether the MR element is defective or non-defective,
wherein when the magnetic field acts upon the tested object, electromagnetic waves are caused to simultaneously act on the tested object to detect the characteristics of the MR element and to judge whether the MR element is defective or non-defective.
